(19) United States
(12) Patent Application Publication
(10) Pub. No.: US 2002/0109206 A1
(43) Pub. Date: Aug. 15, 2002

(54) Lateral PNP-type transistor based on a vertical NPN-structure and process for producing such PNP-type transistor

(76) Inventor: Klaus Schimpf, Freising (DE)

Correspondence Address: TEXAS INSTRUMENTS INCORPORATED, P O BOX 655474, M/S 3999, DALLAS, TX, 75265

(21) Appl. No.: 10/007,917

(22) Filed: Dec. 7, 2001

Related U.S. Application Data
(60) Provisional application No. 60/255,642, filed on Dec. 14, 2000.

(51) Int. Cl. H01L 27/082; H01L 21/331

(52) U.S. Cl. 257/578; 438/335

(57) ABSTRACT

A lateral PNP-type transistor, and a process for producing such lateral PNP-type transistor from a substrate are provided. In particular, a PNP-emitter and a PNP-collector. The PNP-collector is provided at a predetermined distance from the PNP emitter. The PNP-emitter is electrically insulated from the PNP-collector.

### FIELD OF THE INVENTION

The present invention relates generally to lateral PNP-type transistors and methods of making thereof, and in particular to a lateral PNP-type transistor which is based on a vertical NPN-structure and process of producing such PNP-type transistor.

### BACKGROUND INFORMATION

Generally, bipolar transistors consist of two diodes which are coupled in series and which have opposite polarities from another. For example, an NPN-type transistor has a configuration of an NP-PN diode, and the PNP-type transistor has a configuration of an PN-NP diode. These diodes are emitter-base and base-collector diodes. In operation, a small base current (Ib) of the bipolar transistor can control a large collector current (Ic) which allows its amplification. If no base voltage is applied, a barrier between the emitter and the collector does not allow the collector current to flow, even if the collector voltage is applied to the collector. By increasing the base voltage, a base current starts to flow, and the barrier between the emitter and the collector decreases. In this manner, the collector current increases.

The width and doping concentration of the base control the current gain (“hfe”) is defined as follows:

hfe=Ic/Ib

For radio-frequency (“RF”) applications, the speed of the respective device is important. For example, the speed can be characterized by the cutoff frequency value to obtain a current gain. This speed is also effected by the base width. At least for this reason, it is preferable to have a small base width.

Generally, modern analog applications utilize a large variety of various devices on a chip (e.g., MOS transistors, Bipolar-Transistors, Resistors, capacitors etc.). For the RF applications, a BiCMOS process is typically used to integrate a high-speed NPN-bipolar transistor (to be used for the RF functions) with a CMOS part (NMOS/PMOS) (to be used for the digital functions). However, this process is expensive because it requires many processing steps for the two different device-types (i.e., the NPN-type and MOS-type transistors). In certain situations, it may preferable to include an additional PNP-type transistor. However, while it is possible to add such transistor, its addition would compound further costs to the manufacture of the device whose manufacturing costs are already significant. Accordingly, it is preferable to provide a method and system which would facilitate a non-expensive fabrication of the above-described devices.

The conventional approach to utilized a non-expensive fabrication technique has been to provide a lateral layout. With such approach, the emitter, the base and the collector are laterally oriented, an orientation which is opposite to the vertical orientation of the NPN-type transistor. In addition, modern silicon processes used for the RF applications are usually based on the BiCMOS technology. These processes integrate a high-speed vertical NPN-type bipolar transistor within a CMOS process.

Nevertheless, it may be desired to utilize the PNP-type transistors in these processes. To avoid additional costs for fabricating this device, the lateral PNP-type transistors are usually preferred because they can be fabricated without (or with only a few) additional process steps. These lateral PNP-type transistors can, for example, be based on a PMOS-type structure. However, the base width of the resulting devices is limited by the lateral resolution of the process (e.g. the poly-silicon gate length). Indeed, some of the disadvantages of such lateral orientations are that the base width has a lateral dimension (i.e., it is limited by lithography), and the alignment tolerances of the photo processes have to be taken into consideration.

### SUMMARY OF THE INVENTION

One of the objects of the present invention is to overcome these disadvantages by using, e.g., a basic NPN process flow.

Accordingly, an exemplary embodiment of the present invention provides a lateral PNP-type transistor, and a process for producing such lateral PNP-type transistor (or lateral PNP-type transistor) from a substrate. In particular, a PNP-emitter and a PNP-collector. The PNP-collector is provided at a predetermined distance from the PNP emitter. The PNP-emitter is electrically insulated from the PNP-collector.

In one exemplary embodiment of the present invention, a self-aligned spacer technology can be utilized (i.e., a self-aligned process for a base definition) to obtain the base width which is preferably below the limits of lithography.

In another embodiment of the present invention, a PNP-base is provided between the PNP-emitter and the PNP-collector. In addition, the PNP-base may have a shape of a ring.

In a further embodiment of the present invention, a window can be etched in the PNP-type transistor for providing the PNP-base. Also, a spacer may be arranged in the window for reducing the width of the window and the PNP-base may be self aligned.

In yet another embodiment of the present invention, the lateral PNP-type transistor is produced substantially based on a procedure to manufacture a vertical NPN-type transistor. In still another embodiment of the process for producing this lateral PNP-type transistor at least a part of the procedure is performed using a conventional BiCMOS or bipolar process flow.

### BRIEF DESCRIPTION OF THE DRAWINGS

For a complete understanding of the present invention and the advantages thereof, a reference is now made to the following description taken in conjunction with the accompanying drawings, wherein like reference numeral represent like parts, in which:

FIG. 1 shows a first step of an exemplary BiCMOS or bipolar process according to the present invention for producing a lateral PNP-type transistor in which n-type an p-type barrier layers (or diffusion under film layers—“DUF”) are formed.

FIG. 2 shows a second step of the exemplary process in which P-type DUF is implanted.

FIG. 3 shows a third step of the exemplary process in which a silicon epitaxial layer is grown, and n- and p-type wells are defined.

FIG. 4 shows a fourth step of the exemplary process in which a field oxide (FOX) is grown for isolating adjacent devices.

FIG. 5 shows a fifth step of the exemplary process in which a resistive connection is formed between N-type DUF and the surface by an N-implant.

FIG. 6 shows a sixth step of the exemplary process in which gate oxide and poly-silicon are grown.

FIG. 7 shows a seventh step of the exemplary process in which layers of boron-silicon glass and silicon nitride are deposited on the substrate.

FIG. 8 shows an eighth step of the exemplary process in which another poly-silicon layer is deposited on the substrate, and implanted with boron.

FIG. 9 shows a ninth step of the exemplary process in which the boron-silicon glass stack is etched in the substrate.

FIG. 10 shows a tenth step of the exemplary process in which a resist remains in the PNP-type transistor after patterning, and blocks a boron implant used for a simultaneously produced vertical NPN-type transistor.

FIG. 11 shows an eleventh step of the exemplary process in which the resist blocks a base emitter.

FIG. 12 shows a twelfth step of the exemplary process in which emitter poly-silicon and emitter oxide are deposited and removed on open areas after patterning.

FIG. 13 shows a thirteenth step of the exemplary process in which the poly-silicon on the collector contact is removed.

FIG. 14 shows an eleventh step of the exemplary process in which titanium silicide is formed on all open silicon, and illustrates the lateral PNP-type transistor according to the present invention.

### DETAILED DESCRIPTION OF THE INVENTION

The preferred embodiment of the present invention and its advantages are best understood by referring now in more detail to the drawings which like numeral refer to like parts.

A preferred embodiment of a lateral PNP-type transistor, and the process to manufacture such lateral PNP-type transistor is preferably based on the structure and production of a vertical NPN-type transistor. This embodiment provides that a base implant is blocked. In this manner, an ohmic connection between an NPN-emitter and an NPN-collector of the transistor is created, along with a production of a lateral series of P-, N-, P-type silicon which can be used for the PNP-type transistor. The NPN-base implant can be blocked, e.g., by electrically isolating or insulating two NPN-base poly-silicon connections on both sides of an NPN-emitter. Such arrangement can be obtained by, e.g., the use of a ring-shaped NPN-emitter with an inner NPN-base and an NPN-outer base.

The NPN-connections of the NPN-type transistor can be corresponded to PNP-type connections of the PNP-type transistor in the following manner:

| NPN | PNP |
|---|---|
| Emitter | Base |
| Base-inner | Emitter |
| Base-outer | Collector |
| Collector | Base |

The method and lateral PNP-type transistor according to the present invention is advantageous in that the base width is not limited by lithography because the width of the base window (as shall be described below) is reduced by a spacer for the NPN-emitter. Additionally, the PNP base is formed in a self-aligned manner. Accordingly, no alignment tolerances important for lateral structures have to be taken into consideration. It is also conceivable to further modify the basic NPN process, e.g., by increasing the PNP base doping by an N-type implant through an emitter window.

Exemplary process steps for manufacturing the lateral PNP-type transistor and the structure of the lateral PNP-type transistor according to the present invention are described in further detail below. In particular, this description is provided e.g., for the bipolar part of a BiCMOS process flow which can be used as a baseline process for the fabrication of the lateral PNP-type transistor. However, it should be understood that it is possible to utilize other process steps according to the present invention (e.g. pure bipolar manufacturing steps, alternative BiCMOS production steps, etc.). This is because for the production of the PNP-type transistor, only the general structure of the NPN-type transistor preferably utilized.

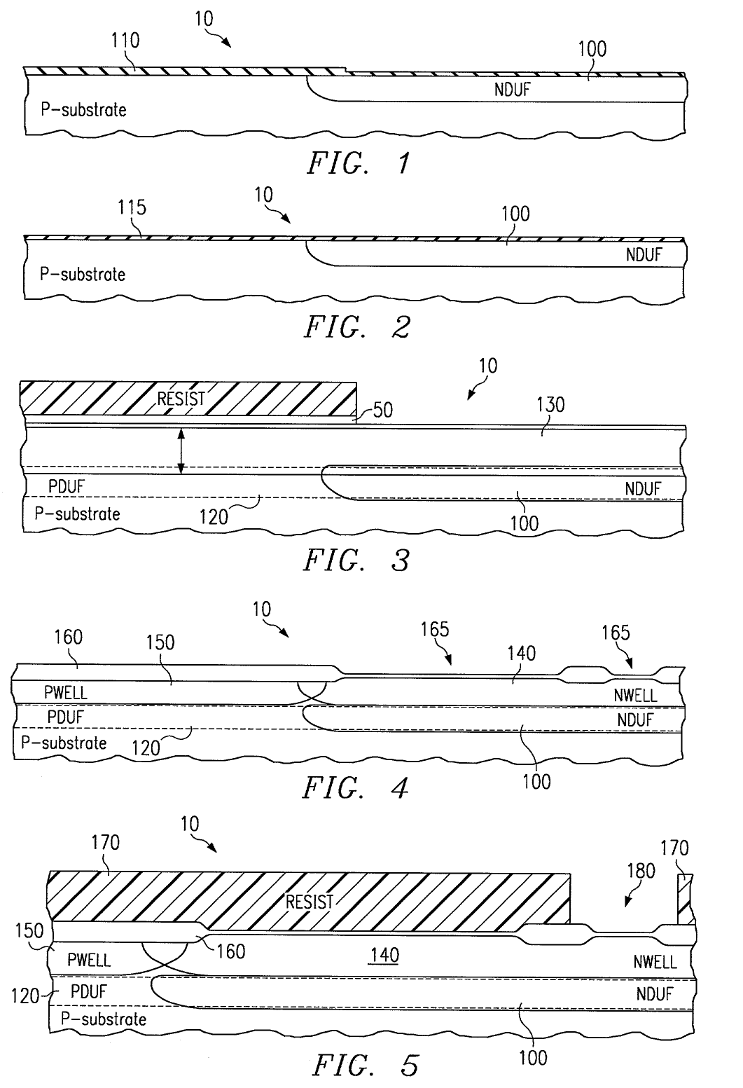

FIG. 1 shows the first step of the exemplary process according to the present invention in which the formation of n- and p-type buried layers (or diffusion under film layers—DUFs) is effectuated. These DUFs are advantageously used for isolating or insulating certain devices. In particular, an oxide which has a thickness of, e.g., 800 nm is grown on the substrate 10 to form an oxide mask 110. Then, this oxide mask 110 is patterned, and a highly N-doped region (NDUF) 100 is implanted into the substrate 10. The NDUF 100 can later be used as a connection for a PNP-base base of the lateral PNP-type transistor according to the present invention (or for a NPN-collector of the conventional NPN-type transistor). FIG. 2 shows the second step of the exemplary process according to the present invention, in which the oxide mask 110 is removed, and a new oxide mask 115 is grown.

FIG. 3 shows the third step of the exemplary process in which, after the removal of the oxide mask 110, a P-type DUF (or PDUF) layer 120 can be implanted into the substrate 10. The PDUF layer 120 can be unpatterned because its concentration is preferably lower than that of the NDUF 100. FIG. 3 also shows that a silicon epitaxial layer 130 is grown on top of the PDUF layer 120 for a width of, e.g., 500 μμthe present invention, in which a field oxide (FOX) 160 is grown for a width of, e.g., 620 nm, so as to isolate (or insulate) the adjacent elements from one another. Before such growth takes place, a nitride layer 50 is grown on the substrate 10 and then etched (along with a portion of the silicon epitaxial layer 130) as shown in FIG. 3. Certain regions 165 of the substrate 10 that are not covered by the FOX 160 may later act as active areas of the respective elements or devices. FIG. 5 shows the fifth step of the process according to present invention in which a resist 170 is patterned to expose a contact of the base of the lateral PNP-type transistor (corresponding to the collector of the NPN-type transistor), and phosphorus is implanted in the substrate 10 at the exposed location 180. In this manner, an N implant (DEEPN) 190 is formed to be the low resistive connection after patterning the resist 170 so as to form the PNP-base contact.

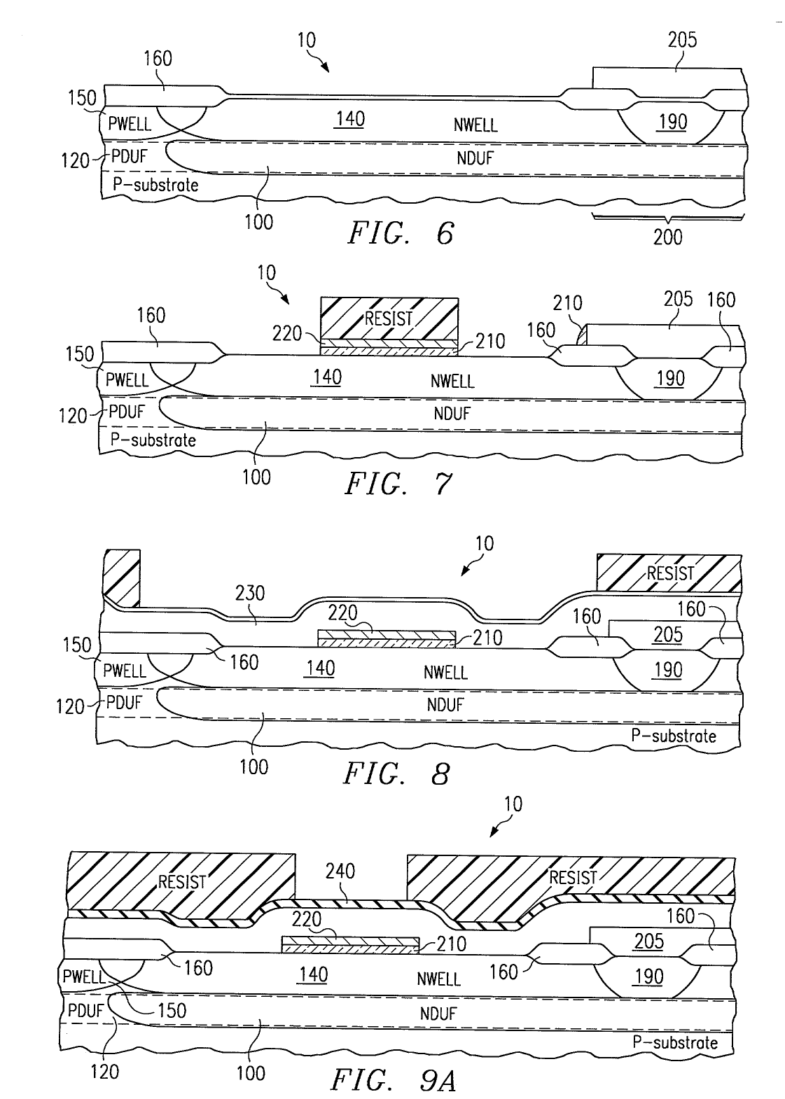

FIG. 6 shows the sixth step of the process according to the present invention, in which the gate-oxide is grown, and which is then followed by a growth of poly-silicon 205. Then, the poly-silicon is removed from all surfaces of the substrate, except from an NPN-type collector 200. Then, as shown in FIG. 7 (i.e., step seven of the process), the layers of boron-silicon-glass (BSG) 210 and of SiN 220 are deposited on the surface of the substrate 10. These layers of BSG 210 are used as a boron source to lower the extrinsic base resistance of the NPN-type transistor at certain surface areas of the substrate 10, while removing the respective portions of this BSG/SiN stack 210, 220 from other surface areas thereof.

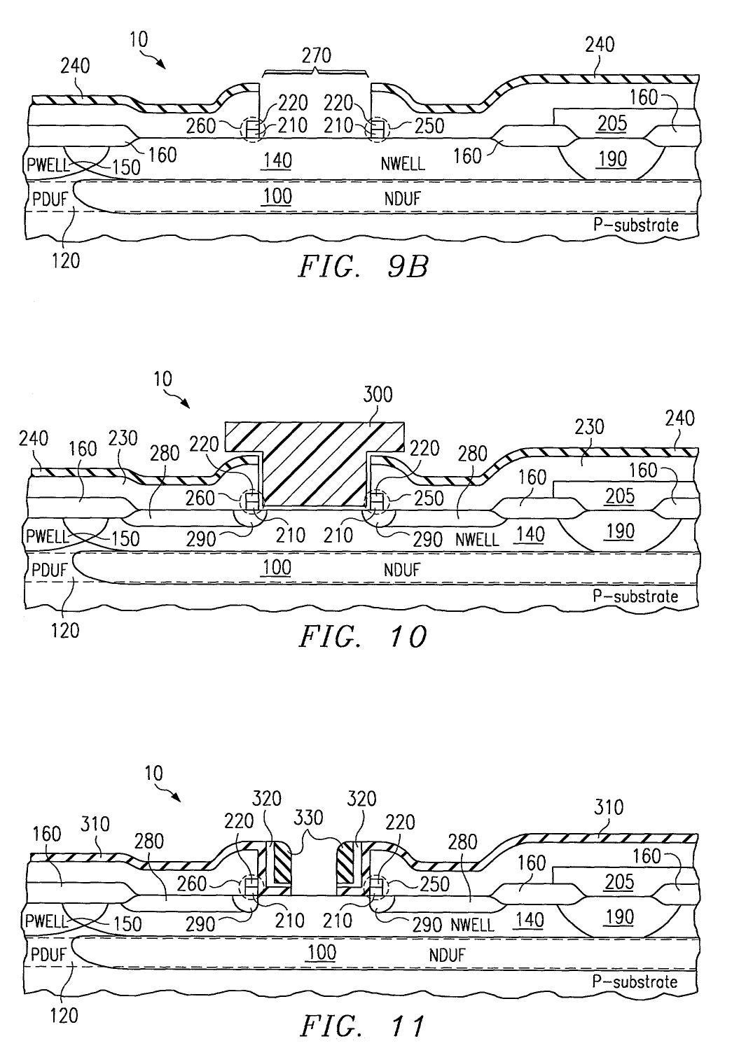

FIG. 8 shows the eighth step of the process according to the present invention. In this step, another poly-silicon layer 230 is grown on the substrate 10, and then boron is implanted in the substrate 10 after patterning the poly-silicon layer 230. At a later point, this layer 230 may act as a PNP-emitter and a PNP-collector FIG. 9 shows a ninth step of the exemplary process according to the present invention. In this step, after the deposition of an oxide layer 240 and patterning it, the BSG/SiN stack 210, 220 is etched down to the substrate along the pattern used for etching the oxide 240. Only small portions 250, 260 of the BSG/SiN stack 210, 220 remain on the sides of a patterned window 270.

After a resist 300 is removed from all areas except from the patterned window 270, a thermal anneal drives the boron doping from base poly-silicon into the substrate 10 to form an extrinsic NPN-base 280, and from the BSG 210 into the substrate 10 to form a base link 290 (as shown in FIG. 10). For the conventional NPN-type transistors, an NPN-intrinsic base is generally implanted into the substrate 10. For the PNP-type transistor according to the present invention, the NPN-base implant is blocked, e.g., by a resist. This can be done by patterning an NPN-base block in the lateral PNP-type transistor. Thus, the resist blocks the base implant so as to prevent any boron to be provided in the window 270. In this manner, the intrinsic base is defined.

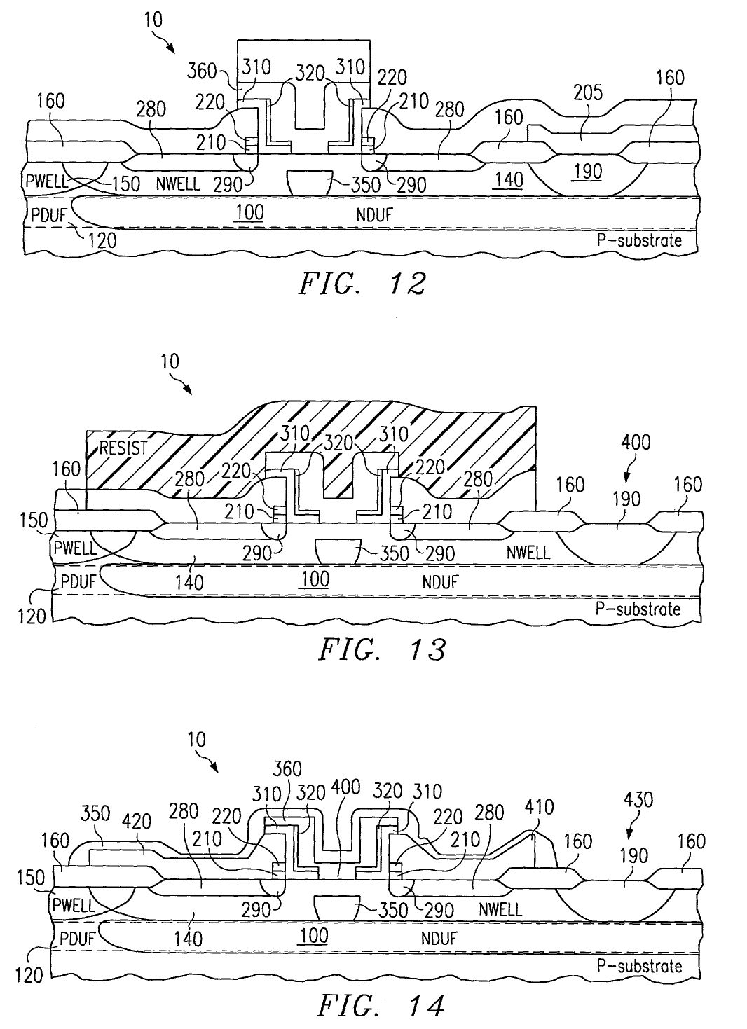

FIG. 11 shows the eleventh step of the exemplary process of the present invention, in which the self-aligned emitter (for the NPN) is defined, and which acts as a base for the PNP-type transistor according to the present invention. Initially, a stack of thin oxide 310, nitride 320, thick oxide 330 is deposited on the substrate 10 within the window 270, and then it is anisotropically etched. The nitride 320 has a thickness of, e.g., 80 μm, and the thick oxide has a thickness of, e.g., 325 nm. Thus, the width of the PNP-base is defined as the width of the window 270 minus two (2) times the thickness of the thin oxide/nitride/thick oxide stack 310, 320, 330. Thus, the width is not limited by the lithography. In addition, even smaller windows than for the NPN-type transistor can be used for the lateral PNP-type transistor of the present invention, if desired.

As shown in FIG. 12, a high energy n-implant through the emitter window 270 preferably defines an NPN-sub-collector 350. The concentration of the sub-collector 350 may also define the doping concentration of the PNP-base, and therefore of the gain of the PNP-type transistor. The emitter (of the NPN-type transistor which corresponds to the base of the PNP-type transistor) is defined by depositing an emitter poly-silicon 360 in the window 270, implanting an arsenic for the emitter doping and driving-in the emitter 360 into the substrate 10 during the annealing procedure. The emitter poly-silicon 360 and the thin oxide 310 are then removed from the substrate after a patterning procedure on non-emitter areas. In FIG. 13, the poly-silicon provided over the NPN-collector (corresponding to the PNP-base) contact 400 is removed after the deposition of this poly-silicon. Thereafter, in FIG. 14, the gate poly-silicon for the MOS devices is patterned and etched. Then, nitride 350 is deposited on the substrate and etched to ensure isolation between the base and collector of the PNP-type transistor (i.e., the base and emitter of the NPN); the same is applicable for the Source/Drain and gate of MOS devices. Thereafter, titanium silicide (TiSi) 360 is formed on all areas, except on the nitride 350 for a better contact. The backend processing (contacts, metal, via, etc) has not been depicted, since the conventional process for their formation can be utilized.

FIG. 14 also shows the resultant PNP-base 400, which is provided between the PNP-emitter 420 and the PNP-collector 410. In addition, another PNP-base 430 is shown in FIG. 14. As clearly shown in this drawing, the PNP-emitter 420 is electronically insulated from the PNP-collector.

Although the present invention has been described with a preferred embodiment, various changes and modifications may be suggested to one skilled in the art. It is intended that the present invention encompass such changes and modifications as falling within the scope of the appended claims.

What is claimed is:

1. A process for producing a lateral PNP-type transistor from a substrate, comprising the steps of:
(a) producing a PNP-emitter;
(b) producing a PNP-collector provided at a predetermined distance from the PNP emitter; and
(c) electrically insulating the PNP-emitter from the PNP-collector.

2. The process according to claim 1, further comprising the step of:
(d) providing a PNP-base between the PNP-emitter and the PNP-collector.

3. The process according to claim 2, wherein the PNP-base has a shape of a ring.

4. The process according to claim 2, further comprising the step of:
(e) providing a further connection for the PNP-base using a highly N-doped region and an NPN-collector.

5. The process according to claim 2, further comprising the step of:
(f) implanting first and second extrinsic NPN-bases into a well of the substrate.

6. The process according to claim 5, wherein step (c) includes electrically insulating the first extrinsic NPN-base from the second extrinsic NPN-base.

7. The process according to claim 2, further comprising the steps of:
(g) prior to step (d), etching a window for the PNP-base; and
(h) providing a spacer in the window, the spacer reducing the width of the window.

8. The method according to claim 2, wherein the PNP-base is self aligned.

9. The process according to claim 1, wherein the lateral PNP-type transistor is produced substantially based on a procedure to manufacture a vertical NPN-type transistor.

10. A lateral PNP-type transistor, comprising:
a PNP-emitter; and
a PNP-collector arranged at a predetermined distance from the PNP-emitter, wherein the PNP-emitter is electrically insulated from the PNP-collector.

11. The lateral PNP-type transistor according to claim 10, further comprising:
a PNP-base arranged between the PNP-emitter and the PNP-collector.

12. The lateral PNP-type transistor according to claim 11, wherein the PNP-base has a shape of a ring.

13. The lateral PNP-type transistor according to claim 11, further comprising:
a connection for the PNP-base is provided using a highly N-doped region and an NPN-collector.

14. The lateral PNP-type transistor according to claim 11, further comprising:
first and second extrinsic NPN-bases implanted into a well of the lateral PNP-type transistor.

15. The lateral PNP-type transistor according to claim 14, wherein the first extrinsic NPN-base is electrically insulated from the second extrinsic NPN-base.

16. The lateral PNP-type transistor according to claim 11, wherein a window is etched in the PNP-type transistor for the PNP-base, and further comprising:
a spacer arranged in the window, the spacer reducing the width of the window.

17. The PNP-type transistor according to claim 11, wherein the PNP-base is self aligned.

18. The PNP-type transistor according to claim 10, wherein the lateral PNP-type transistor is produced substantially based on a procedure to manufacture a vertical NPN-type transistor.
